(19) United States
(12) Patent Application Publication
(10) Pub. No.: US 2021/0074336 A1
(43) Pub. Date: Mar. 11, 2021

(54) MEMORY SYSTEM AND POWER SUPPLY CIRCUIT

(71) Applicant: KIOXIA CORPORATION, Tokyo (JP)

(72) Inventors: Kengo KUMAGAI, Yokohama Kanagawa (JP); Takashi YAMASAKI, Yokohama Kanagawa (JP); Nobutaka NAKAMURA, Yokohama Kanagawa (JP)

(21) Appl. No.: 16/802,496

(22) Filed: Feb. 26, 2020

(30) Foreign Application Priority Data
Sep. 10, 2019 (JP) 2019-164855

(51) Int. Cl. G11C 5/14; G11C 14/00; G11C 16/10; G11C 16/30; G11C 11/4096; G11C 11/4074

(52) U.S. Cl. CPC G11C 5/141; G11C 14/0018; G11C 11/4074; G11C 16/30; G11C 11/4096; G11C 16/10

(57) ABSTRACT

A memory system includes a non-volatile memory, a controller that controls writing of data to the non-volatile memory, a power supply circuit that is connected to the non-volatile memory and the controller and generates a plurality of power supply voltages using an external voltage, and at least one capacitor that stores energy that is charged by a charge voltage. The charge voltage is one of the plurality of power supply voltages generated by the power supply circuit. A capacitance of the at least one capacitor is detected and then a value of the charge voltage is set according to the detected capacitance of the at least one capacitor.

### CROSS-REFERENCE TO RELATED APPLICATION

This application is based upon and claims the benefit of priority from Japanese Patent Application No. 2019-164855, filed Sep. 10, 2019, the entire contents of which are incorporated herein by reference.

### FIELD

Embodiments described herein relate generally to a memory system and a power supply circuit.

### BACKGROUND

A memory system including a non-volatile memory is widely used. As one example of such a memory system, a Solid State Drive (SSD) including a flash memory is known. An SSD is used for various applications, from personal use to business use. In an SSD for some applications, the data to be written in the flash memory is first temporarily stored in a volatile memory, such as a DRAM. The data written and stored in the volatile memory can be lost when an external power supply is unintentionally shut off.

In order to prevent data loss, a Power Loss Protection (PLP) function is provided in the SSD. In order to implement a PLP function, it is generally necessary to provide a backup power supply. A capacitor (also referred to more specifically as a PLP capacitor in some contexts) can be used as the backup power supply. Electric energy (hereinafter, simply referred to as energy) is constantly supplied to the PLP capacitor. When the external power supply shuts off, the charged energy of the PLP capacitor is then discharged. Using this energy discharge, the SSD can continue to operate for a limited period of time. For example, when the external power supply is shut off while the data being written is still stored in the DRAM, the data in the DRAM can be written into the flash memory using the provided the backup power supply energy (i.e., from the PLP capacitor).

However, the capacitance of the capacitor decreases due to aging deterioration. The capacitance of the PLP capacitor is set to be a value sufficient to provide the energy necessary for writing the temporarily stored data (in the DRAM or the like) to be written to the flash memory. When the capacitance is reduced due to the aging deterioration, the PLP capacitor cannot store the energy necessary for implementing the PLP function. Therefore, the capacitance of the PLP capacitor is generally checked at a predetermined timing, and when it is detected that the capacitance has decreased to such an extent that the energy necessary for implementing the PLP function cannot be stored/supplied, the SSD is considered to be a failure and can no longer be used in normal operation.

In this manner, even if the flash memory itself is otherwise normal, the SSD is considered to be a failure when the backup power supply capacitor becomes defective due to aging deterioration. Accordingly, a failure rate of the SSD increases due to the defective capacitor.

### DESCRIPTION OF THE DRAWINGS

FIG. 1 is a block diagram showing a configuration of an information processing system including a memory system according to a first embodiment of the present disclosure;

FIG. 2 is a block diagram showing a configuration of a power supply circuit in the memory system according to the first embodiment;

FIG. 3 is a circuit diagram showing a configuration of a DC/DC converter unit in the power supply circuit shown in FIG. 2;

FIG. 4 is a circuit diagram showing a configuration of a PLP capacitor in the memory system according to the first embodiment;

FIG. 5 is a flowchart showing processing of a controller in the memory system according to the first embodiment;

FIGS. 6A and 6B are circuit diagrams showing a configuration of a PLP capacitor in a memory system according to a second embodiment; and

FIG. 7 is a flowchart showing processing of a controller in the memory system according to the second embodiment.

### DETAILED DESCRIPTION

Embodiments provide a memory system and a power supply circuit in which a failure rate can be suppressed from increasing even when a capacitor for a backup power supply is deteriorated due to aging.

In general, according to one embodiment, a memory system includes a non-volatile memory, a controller that controls writing of data to the non-volatile memory, a power supply circuit that is connected to the non-volatile memory and the controller and generates a plurality of power supply voltages using an external voltage, and at least one capacitor that stores energy that is charged by a charge voltage that is one of the plurality of power supply voltages generated by the power supply circuit. A capacitance of the at least one capacitor is detected, and a value of the charge voltage is determined according to the detected capacitance of the at least one capacitor.

Certain example embodiments will be described below with reference to the accompanying drawings. The following describes an apparatus and a method embodying technical concepts of the present disclosure, and the technical concepts of the present disclosure are not particularly limited to the particular structures, shapes, arrangements, materials, and the like of elements described in these examples. Variations that can be conceived by those skilled in the art are also within the contemplated scope of the present disclosure. In order to clarify the description, sizes, thickness, plane sizes, shapes, and the like of elements in the drawings may have be changed or varied and, in general, the all aspects in the drawings are schematically represented rather than to be considered to represent an embodiment according to an actual implementation. In the drawings, elements having different dimensional relationships and ratios may be depicted in simplified manner(s). Furthermore, in the drawings, repeated elements/aspects are generally denoted by using the same reference numerals and redundant description thereof may be omitted. Although certain elements/aspects may be represented as a plurality of similar elements, in general, in these descriptive examples, the depicted number of such similar elements are merely examples and embodiments are not limited to only such numbers of similar or repeated elements. It is also not required that repeated instances of similar elements in these examples be necessarily identical in all possible respects and, in general, any particular instance of a repeated element may have any characteristic within the descriptive range or exemplary types provided for such an element in the associated description. In the following description, use of the term “connection” or “connected” does not require or necessarily imply a direct connection between the elements or aspects stated to have a “connection” therebetween or as being “connected,” but can also include an indirect connection via other elements interposed therebetween.

### First Embodiment

[System Configuration]

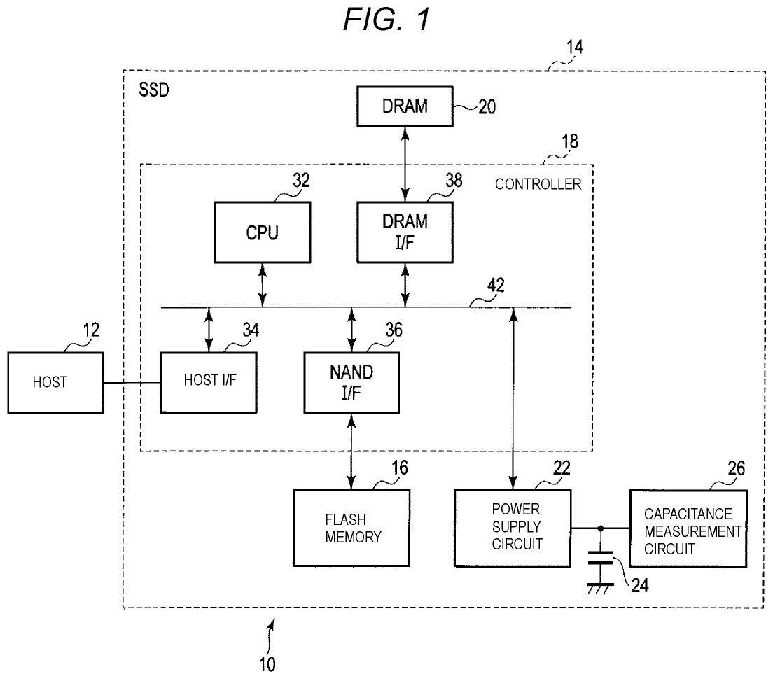

FIG. 1 is a block diagram showing a configuration of an information processing system including a memory system according to a first embodiment of the present disclosure. The memory system is a semiconductor storage device that writes data to a non-volatile memory and reads data from the non-volatile memory. An example of the non-volatile memory includes a NAND flash memory, a NOR flash memory, a Magneto-resistive Random Access Memory (MRAM), a Phase change Random Access Memory (PRAM), a Resistive Random Access Memory (ReRAM), a Ferroelectric Random Access Memory (FeRAM), and the like. In the present application, an example of the non-volatile memory is a NAND flash memory (hereinafter simply referred to as a flash memory).

An information processing system 10 includes a host device (hereinafter simply referred to as a host) 12 and an SSD 14. The host 12 is an information processing device as an external apparatus that accesses the SSD 14. The host 12 may be a server (also referred to as a storage server) that stores a large amount of data in the SSD 14 and/or may be a personal computer.

The SSD 14 is an example of the memory system. The SSD 14 may be used as a main storage of an information processing device functioning as the host 12. The SSD 14 may be provided inside the information processing device, or may be provided outside the information processing device and connected to the information processing device via a cable or a network.

The SSD 14 includes a flash memory 16, a controller 18, a Dynamic Random Access Memory (DRAM) 20, a power supply circuit 22, a PLP capacitor 24, and a capacitance measurement circuit 26. The controller 18 functions as a memory controller that controls the flash memory 16. The controller 18 may be implemented by a circuit such as a System on a chip (SoC).

The DRAM 20 is an example of a volatile memory. The DRAM 20 is, for example, a Double Data Rate 3 Low voltage (DDR3L) DRAM. The DRAM 20 may be provided with a write buffer, a read buffer, a lookup table (LUT) cache area, and a system management information storage area. The write buffer is a buffer area for temporarily storing data to be written in the flash memory 16. The read buffer is a buffer area for temporarily storing data read from the flash memory 16. The LUT cache area is an area for caching an address conversion table (also referred to as a logical address/physical address conversion table). The LUT is a correspondence table between each logical address designated by the host 12 and each physical address of the flash memory 16. The system management information storage area includes various values and various tables used during operation of the SSD 14.

The DRAM 20 as the volatile memory may be provided not only outside the controller 18 but also inside the controller 18. As the volatile memory, a Static Random Access Memory (SRAM) capable of higher speed access may be used instead of the DRAM 20.

The flash memory 16 may include a plurality of flash memory chips (also referred to as flash memory dies). The flash memory 16 may include a memory cell array including a plurality of memory cells arranged in a matrix. The flash memory 16 may have a two-dimensional structure or a three-dimensional structure.

The memory cell array in the flash memory 16 includes a plurality of blocks. Each block includes a plurality of pages. The block functions as a unit of data erase operation. Each of the pages includes a plurality of memory cells connected to the same word line. The pages are units of data write operation and data read operation. Data of one page is data of a write unit or data of a read unit, and may be stored in the DRAM 20. In the case of write operation, data of the write unit of one page read out from the DRAM 20 is written into the flash memory 16. Therefore, when an external power supply is shut off unintentionally during the write operation, data to be written into the flash memory 16 and stored in the DRAM 20 is lost if a backup power supply is not present. In the embodiment, the backup power supply is prepared, and data to be written and stored in the DRAM 20 can be written into the flash memory 16 by using the backup power supply when the external power supply is unintentionally shut off. A word line may be used as a unit of data write operation or data read operation instead of a page. In this case, data of one word line is data of a write unit or data of a read unit.

The power supply circuit 22 generates a plurality of power supply voltages necessary for each device of the SSD from a single external power supply voltage or a plurality of external power supply voltages supplied from the external power supply. In FIG. 1, a power supply line is not shown. The power supply circuit 22 may be implemented by a single integrated circuit (IC) or a plurality of ICs. Information indicating various states of the power supply circuit 22 is transmitted to the controller 18 in accordance with a predetermined communication standard. The communication standard between the power supply circuit 22 and the controller 18 may be, for example, a serial communication standard. An example of the serial communication standard is an Inter-Integrated Circuit (I2C) method. In the specification, the communication standard between the power supply circuit 22 and the controller 18 complies with the I2C method. The controller 18 writes data into the flash memory 16 and reads data from the flash memory 16 in accordance with a command from the host 12. The controller 18 also generates a control signal for controlling a value of a power supply voltage to be generated by the power supply circuit 22 in accordance with a command from the host 12 along with various types of information from the power supply circuit 22. The controller 18 transmits the generated control signal to the power supply circuit 22. As a result, the controller 18 controls generation of the plurality of power supply voltages to be applied to each device of the SSD 14.

The PLP capacitor 24 for the backup power supply is connected to the power supply circuit 22. The PLP capacitor 24 supplies the power supply circuit 22 with energy for data protection when the power supply is unintentionally shut off. The power supply circuit 22 supplies a power supply voltage to the flash memory 16, the controller 18, and the DRAM 20 for a predetermined period of time using the energy of the PLP capacitor 24 after the power is turned off. The capacitance of the PLP capacitor 24 is set to be slightly larger than a target capacitance that can charge energy necessary for implementing a PLP function. This is because if a margin is provided in the capacitance of the PLP capacitor, even if the capacitance of the capacitor is somewhat reduced due to aging deterioration, the PLP function can be continuously implemented, and a failure rate can be kept low. For example, in order to be able to implement the PLP function even if the capacitance is decreased by 30% from the initial capacitance, the initial capacitance of the PLP capacitor may be set to about 1.43 times the target capacitance. As an example of the PLP capacitor 24, an electric double layer capacitor, a conductive polymer aluminum electrolytic capacitor, a conductive polymer tantalum solid electrolytic capacitor, or the like may be used.

The capacitance measurement circuit 26 is connected to the PLP capacitor 24. The capacitance measurement circuit 26 measures the electrostatic capacitance of the PLP capacitor 24 and supplies the measurement result to the power supply circuit 22.

The controller 18 includes a CPU 32, a host interface (a host I/F) 34, a NAND interface (NAND I/F) 36, a DRAM interface (DRAM I/F) 38, and the like.

The CPU 32, the host I/F 34, the NAND I/F 36, and the DRAM I/F 38 are connected to a bus line 42. The CPU 32 executes firmware stored in the flash memory 16 and implements various functions. One example of the various functions is control of power generation operation by the power supply circuit 22 including charge voltage control of the PLP capacitor 24.

The host 12 is electrically connected to the host I/F 34, the flash memory 16 is electrically connected to the NAND I/F 36, and the DRAM 20 is electrically connected to the DRAM I/F 38.

The host I/F 34 that electrically connects the host and the SSD 14 conforms to a standard such as Small Computer System Interface (SCSI), Serial Attached SCSI (SAS), AT Attachment(ATA), Serial ATA (SATA), PCI Express® (PCIe), Ethernet, Fiber channel, NVM Express® (NVMe), Universal Serial Bus (USB), and Universal Asynchronous Receiver/Transmitter (UART).

The NAND I/F 36 that electrically connects the controller 18 and the flash memory 16 conforms to a standard such as Toggle DDR, and Open NAND Flash Interface (ONFI). The NAND I/F 36 functions as a NAND control circuit that controls the flash memory 16. The NAND I/F 36 may be connected to a plurality of chips in the flash memory 16 via a plurality of channels.

[Configuration of Power Supply Circuit 22]

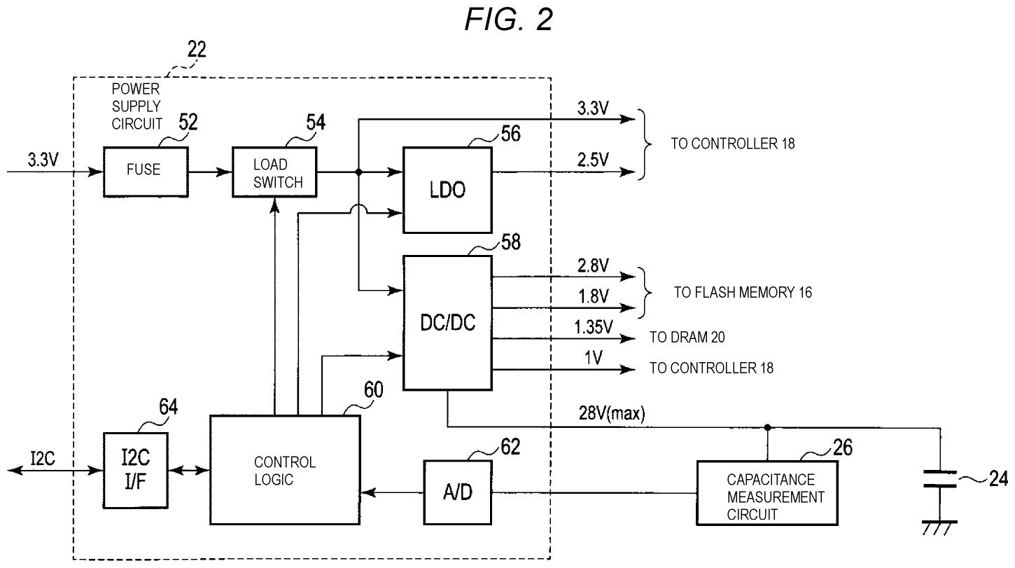

FIG. 2 shows an example of a configuration of the power supply circuit 22. Although numerical values of voltages are described for convenience of description, the numerical values are merely examples and may be freely changed. The number of voltages to be generated is also an example and may be freely changed. The external power supply (not shown) generates an external power supply voltage of, for example, DC 3.3 V (or DC 5 V). Hereinafter, the voltage is a DC voltage and a notation of DC is omitted. A current corresponding to the external power supply voltage of 3.3 V is supplied to a Low Dropout (LDO) regulator 56 and a DC/DC converter 58 via a fuse 52 and a load switch 54 in series. The host 12 may include the external power supply, and a current corresponding to the external power supply voltage may be supplied from the host 12 to the power supply circuit 22. An IC constituting the power supply circuit 22 may be referred to as a Power Management IC (PMIC).

The fuse 52 may be implemented by a metal fuse to be blown when an overcurrent exceeding a certain current flows thereto. When the fuse 52 is blown (i.e., opened), the external power supply voltage is not applied to the load switch 54 unless the fuse is replaced. The fuse 52 is not limited to the metal fuse, and may be implemented by an electronic fuse that becomes non-conductive (opened) when an overcurrent is detected.

The load switch 54 is an ON/OFF switch, and is normally in an ON state. In the ON state, the load switch 54 outputs a voltage obtained by lowering a dropout voltage from the applied voltage. For convenience of description, it is assumed here that the dropout voltage is 0 V, and the load switch 54 outputs the voltage of 3.3 V in the ON state. Similarly to the fuse 52, when an overcurrent exceeding a certain current flows, the load switch 54 is brought into the OFF state. In the OFF state, the load switch 54 outputs 0 V. A value of the overcurrent at which the fuse 52 is blown may be higher or lower than a value of the overcurrent at which the load switch 54 changes from the ON state to the OFF state, or may be the same. The overcurrent is doubly prevented from being supplied to the LDO regulator 56 and the DC/DC converter 58 by the fuse 52 and the load switch 54.

The LDO regulator 56 is a circuit that outputs a power supply voltage of a device of the SSD 14 that requires a small current. The DC/DC converter 58 is a circuit that outputs a power supply voltage of a device of the SSD 14 that requires a large current. The LDO regulator 56 and the DC/DC converter 58 may be implemented by individual ICs or may be implemented by a single IC.

The LDO regulator 56 steps down the external power supply voltage of 3.3 V output from the load switch 54 to generate a power supply voltage of 2.5 V. The external power supply voltage may be used as it is and output from the power supply circuit 22 as a power supply voltage of 3.3 V. The power supply voltages of 3.3 V and 2.5 V are supplied to the controller 18.

The DC/DC converter 58 steps up or steps down the output voltage (3.3 V) of the load switch 54 to generate a plurality of power supply voltages required by each device of the SSD 14. The DC/DC converter 58 includes a plurality of DC/DC converter units that perform the step up or step down to generate the plurality of voltages, respectively.

A step-up DC/DC converter unit steps up the output voltage of the load switch 54 and generates a power supply voltage of 28 V. The power supply voltage of 28 V is applied to the PLP capacitor 24 as a charge voltage. The output voltage of the step-up DC/DC converter unit is a variable voltage and a maximum value is 28 V. The higher the applied voltage, the more likely the capacitor is short-circuited. An upper limit of the voltage that can be applied to the capacitor is determined accordingly. The maximum allowable voltage that can be applied to the PLP capacitor 24 is 28 V.

A step-down DC/DC converter unit steps down the output voltage of the load switch 54 to generate a power supply voltage of 2.8 V, 1.8 V, 1.35 V, and 1 V. The power supply voltages of 2.8 V and 1.8 V are applied to the flash memory 16. The power supply voltage of 1.35 V is applied to the DRAM 20. The power supply voltage of 1 V is applied to the controller 18.

The measurement result of the capacitance measurement circuit 26 is input to a control logic 60 via an analog-to-digital converter (an A/D converter) 62. Although not shown, output of a temperature sensor that measures temperature of the SSD 14 and a detection result of an overcurrent of each device of the SSD 14 are also input to the control logic 60. The control logic 60 transmits input data to the controller 18 in accordance with the I2C method, and receives a control signal transmitted from the controller 18 in accordance with the I2C method.

Since the power supply voltage generated by the power supply circuit 22 varies with the temperature of the SSD 14, the controller 18 supplies the power supply circuit 22 with a control signal for adjusting the voltage generated by the power supply circuit 22 according to the temperature. When an overcurrent is detected, the controller 18 supplies the power supply circuit 22 with a control signal for stopping the generation of the voltage applied to a device through which the detected overcurrent flows. When an overcurrent of the device to which 3.3 V is applied is detected, the controller 18 supplies a control signal for turning off the load switch 54 to the power supply circuit 22. Furthermore, the controller 18 also supplies a control signal for controlling operation of the DC/DC converter 58 to the power supply circuit 22 in order to change a charge voltage for the PLP capacitor 24. The control logic 60 provides control signals to the load switch 54, the LDO regulator 56, and the DC/DC converter 58 in response to a control signal from the controller 18.

An I2C I/F 64 is connected to the control logic 60 and communicates with the controller 18 in response to a control signal from the control logic 60.

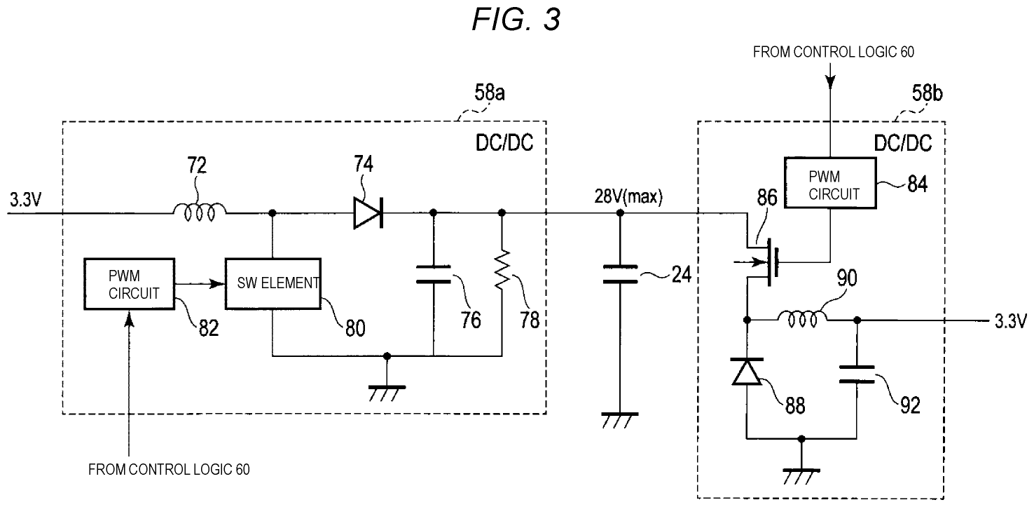

The LDO regulator 56 and the DC/DC converter 58 are well known as voltage converters. As an example, configurations of a step-up DC/DC converter unit 58a and a step-down DC/DC converter unit 58b are shown in FIG. 3. The step-up DC/DC converter unit 58a steps up the output voltage 3.3 V of the load switch 54 to 28 V (the maximum allowable voltage that can be applied to the PLP), and charges the PLP capacitor 24. The step-down DC/DC converter unit 58b receives a discharge current of the PLP capacitor 24 and steps down the output voltage 28 V of the PLP capacitor 24 to 3.3 V.

The step-up DC/DC converter unit 58a includes an inductor 72 and a diode 74 connected in series and a capacitor 76 and a resistor 78 connected in parallel. An input current generated from an input voltage (3.3 V) is input to one terminal of the inductor 72. The other terminal of the inductor 72 is connected to an anode terminal of the diode 74 and is grounded via a switching element (an SW element) 80. A cathode terminal of the diode 74 is grounded via the capacitor 76 and the resistor 78 connected in parallel. A terminal voltage of the resistor 78 is an output voltage of the DC/DC converter unit 58a, and is applied to the PLP capacitor 24.

The switching element 80 may be implemented by a metal-oxide-semiconductor field-effect transistor (MOSFET) or the like. A pulse width modulation circuit 82 (also referred to as a PWM circuit 82) is connected to a control terminal of the switching element 80. The PWM circuit 82 controls ON/OFF of the switching element 80 based on a control signal from the control logic 60. During an ON period of the switching element 80, an input voltage is applied to the inductor 72, and a current flowing through the inductor 72 increases. During an OFF period of the switching element 80, the diode 74 becomes a positive bias, the current of the inductor 72 is reduced, energy is charged to the capacitor 76, and a voltage higher than the input voltage is generated across the resistor 78. A cycle of a pulse signal output from the PWM circuit 82 is constant, and the switching element 80 is periodically turned on and off. A voltage output from the DC/DC converter unit 58a, that is, a charge voltage for the PLP capacitor 24 changes according to a ratio of the ON period in one cycle of the switching element 80 (also referred to as a duty ratio of an ON pulse). When the maximum allowable voltage that can be applied to the PLP capacitor 24 is 28 V, the maximum value of the output voltage of the DC/DC converter unit 58a is 28 V. The control logic 60 notifies the PWM circuit 82 of such a duty ratio that the output voltage of the DC/DC converter unit 58a becomes 28 V.

The step-down DC/DC converter unit 58b includes a switching element (e.g., a MOSFET) 86 whose drain terminal is connected to the PLP capacitor 24. The MOSFET 86 is an example of the switching element. A gate terminal of the MOSFET 86 is connected to a PWM circuit 84. The PWM circuit controls ON/OFF of the MOSFET 86 based on a control signal from the control logic 60. A source terminal of the MOSFET 86 is connected to a cathode terminal of the diode 88, and is grounded via a series circuit of an inductor 90 and a capacitor 92. An anode terminal of the diode 88 is grounded. A connection point between the inductor 90 and the capacitor 92 serves as an output terminal.

When the MOSFET 86 is turned on, a discharge current from the PLP capacitor 24 flows to the output terminal via the inductor 90, and the capacitor 92 is charged. In a case of an ideal DC/DC converter having 100% efficiency, Vin×Iin=Vout×Iout (where Vin is an input voltage, Vout is an output voltage, Iin is an input current, and Iout is an output current). During stepping down, the output current needs to be larger than the input current. Therefore, when the MOSFET 86 is turned off, a current is drawn from the ground via the diode 88 and the inductor 90 by the energy charged in the capacitor 92, and the current is output from the output terminal.

A cycle of a pulse signal output from the PWM circuit 84 is constant, and the MOSFET 86 is periodically turned on and off. The voltage output from the DC/DC converter unit 58b changes according to a duty ratio of the MOSFET 86. The control logic 60 notifies the PWM circuit 84 of such a duty ratio that the output voltage of the DC/DC converter unit 58b is 3.3 V.

The output voltage of 3.3 V is applied to the DC/DC converter 58 instead of the output voltage of the load switch 54, and is stepped down by the step-down DC/DC converter unit, so that power supply voltages of 2.8 V, 1.8 V, 1.35 V, and 1 V are generated.

[Configuration of PLP Capacitor 24]

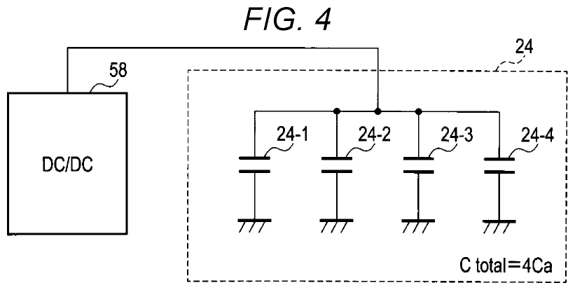

Although the PLP capacitor 24 is implemented by a single capacitor in the above description, as shown in FIG. 4, the PLP capacitor 24 may include four capacitors 24-1, 24-2, 24-3, and 24-4 connected in parallel. The number of capacitors connected in parallel is not limited to four, and may be ten or more. By constituting the PLP capacitor by a plurality of capacitors, a relatively small capacitor can be used. Even if the necessary energy cannot be charged by a single capacitor, it is possible to charge the PLP capacitor 24 with energy necessary for implementing the PLP function by connecting a large number of capacitors in parallel. When the PLP capacitor 24 is implemented by a plurality of capacitors connected in parallel, the capacitance measurement circuit 26 measures a combined capacitance of the plurality of capacitors (here Ctotal=4 Ca, where Ca is the capacitance of each capacitor).

[Operation Example]

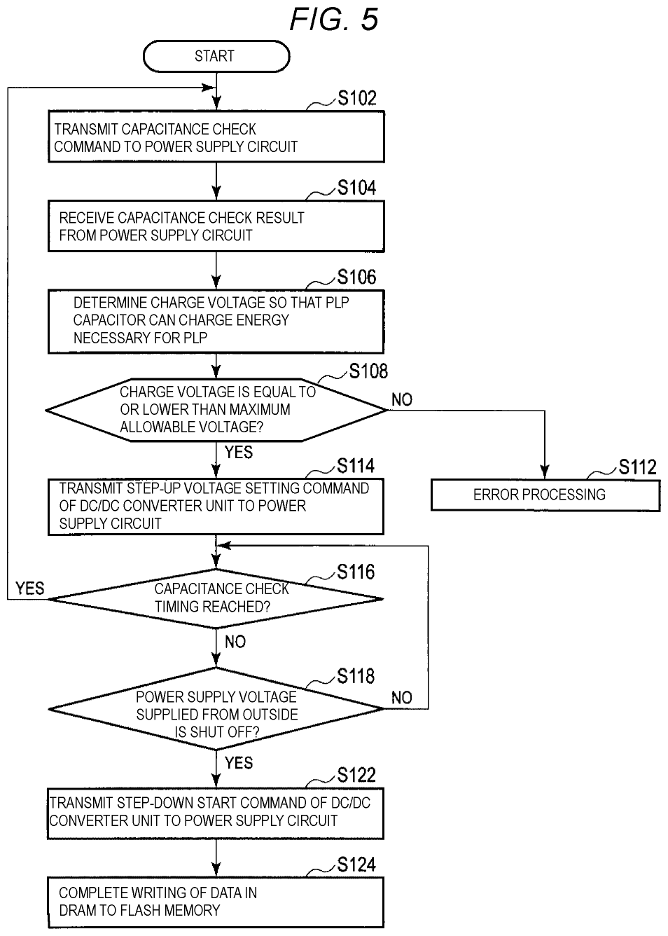

An example of processing related to PLP of the controller 18 will be described with reference to FIG. 5. When a power supply of the SSD 14 is turned on, the controller 18 transmits a capacitance check command to the power supply circuit 22 in step S102. When the control logic 60 of the power supply circuit 22 receives the capacitance check command via the I2C I/F 64, the control logic 60 notifies the PWM circuit 82 of the DC/DC converter unit 58a of such a duty ratio that the DC/DC converter unit 58a outputs 28 V. Accordingly, the PWM circuit 82 controls ON/OFF of the switching element 80, a charge voltage of 28 V is applied to the PLP capacitor 24, and the energy is charged to the PLP capacitor 24. Thereafter, the capacitance measurement circuit 26 measures the capacitance of the PLP capacitor 24. The measurement result is input to the control logic 60 via the A/D converter 62. The control logic 60 transmits the capacitance check result by the capacitance measurement circuit 26 to the controller 18 via the I2C I/F 64.

In step S104, the controller 18 receives the capacitance check result transmitted from the power supply circuit 22.

In step S106, the controller 18 determines a target value of a charge voltage so that the PLP capacitor 24 can charge the energy necessary for implementing the PLP function.

An energy amount Q (in joules) charged in a capacitor is (½) CV², and is determined by the capacitance C of the capacitor and a charge voltage V. Therefore, even if the capacitance of the capacitor is decreased, if the charge voltage is increased, a certain amount of energy is charged into the capacitor. As described above, the initial capacitance of the PLP capacitor 24 is set to be slightly larger than the target capacitance necessary for implementing the PLP function.

For example, when the energy necessary for implementing the PLP function is 100 mJ and the PLP capacitor 24 is charged at 28 V, which is the maximum voltage of the DC/DC converter unit 58a, a target capacitance of the capacitor is 280 μF. However, in the present embodiment, the initial capacitance of the PLP capacitor 24 is set to 400 μF in anticipation of a certain degree of aging deterioration. Therefore, as long as the amount of decrease in the capacitance of the PLP capacitor 24 is within 30% of this initial capacitance, the PLP function can be implemented. Accordingly, even when the capacitance of the PLP capacitor 24 is decreased to some extent due to aging deterioration, the SSD 14 is not immediately unusable, and the life of the SSD 14 can be extended.

In this manner, when the 400 μF PLP capacitor 24 designed with a margin is charged at 28 V, energy of about 157 mJ is charged to the PLP capacitor 24. Since energy necessary for implementing the PLP function is 100 mJ, energy of about 1.5 times the necessary energy is charged to the PLP capacitor 24 at a charge voltage of 28 V, and about ⅓ of the energy is excessively charged. When the capacitance of the PLP capacitor 24 decreases to 280 μF due to the aging deterioration, energy of about 110 mJ is charged to the PLP capacitor 24 by charging at 28 V. In the present embodiment, by controlling the charge voltage so that a minimum necessary energy is charged in accordance with the capacitance of the PLP capacitor, unnecessary energy is prevented from being charged.

Therefore, in step S106, the charge voltage sufficient for the PLP capacitor 24 to charge energy necessary for implementing the PLP function is calculated based on the measurement result of the capacitance of the PLP capacitor 24. For example, when the capacitance is 400 μF, the charge voltage may be 23 V for the PLP capacitor 24 to charge the energy of 100 mJ. In this way, when the PLP capacitor 24 is not deteriorated, the charge voltage can be set to be lower than the maximum allowable voltage (which is 28 V in this instance). In general, since the capacitor is likely to be short-circuited when an applied voltage is high, making the charge voltage lower than the maximum allowable voltage can reduce the possibility that the PLP capacitor 24 will cause a short-circuit failure. As a result, the life of the SSD 14 can be extended.

Since the maximum allowable voltage of the PLP capacitor 24 is determined, the controller 18 determines in step S108 whether the charge voltage calculated in step S106 is equal to or lower than the maximum allowable voltage (=28 V). When the charge voltage calculated in step S106 is not equal to or lower than the maximum allowable voltage (NO in step S108), the controller 18 performs error processing in step S112. An example of the error processing is to inform a user that the PLP capacitor 24 is defective and sufficient energy is not charged to the PLP capacitor 24 and the PLP function may not be performed.

When the charge voltage calculated in step S106 is equal to or lower than the maximum allowable voltage (YES in step S108), in step S114, the controller 18 transmits a step-up voltage setting command to the power supply circuit 22 so that a step-up voltage of the DC/DC converter unit 58a becomes equal to the charge voltage calculated in step S106. When the control logic 60 receives the step-up voltage setting command, the control logic 60 notifies the PWM circuit 82 of the DC/DC converter unit 58a of such a duty ratio that the DC/DC converter unit 58a outputs the set voltage.

Thereafter, the DC/DC converter unit 58a outputs the charge voltage calculated in step S106, and the PLP capacitor 24 is always charged with energy necessary for implementing the PLP function.

In step S116, the controller 18 determines whether capacitance check timing is reached. Since the SSD 14 may operate continuously, deterioration of the PLP capacitor 24 may be diagnosed not only immediately after the power is turned on (that is, during initialization or the like) but also periodically (for example, once a week or every day). Therefore, every time the capacitance check timing is reached (YES in step S116), the controller 18 executes the processing of step S102. When the capacitance check timing is not reached (NO in step S116), the controller 18 determines whether a power supply voltage supplied from the outside is shut off in step S118. When the power supply voltage supplied from the outside is not shut off (NO in step S118), the controller 18 repeats the determination of step S116.

When the power supply voltage supplied from the outside is shut off (YES in step S118), the controller 18 transmits a step-down start command for the DC/DC converter unit 58b to the power supply circuit 22 in step S122. When the control logic 60 receives the step-down start command, the control logic 60 notifies the PWM circuit 82 of such a duty ratio that the DC/DC converter unit 58b outputs 3.3 V. Accordingly, the PWM circuit 82 controls ON/OFF of the MOSFET 86. Accordingly, the output voltage of the DC/DC converter unit 58b is maintained at 3.3 V for a certain period of time. Since the output voltage of the DC/DC converter unit 58b is maintained at 3.3 V, even when the power supply voltage supplied from the outside is shut off and the output voltage of the load switch 54 is 0 V, a voltage of 3.3 V is input to a step-down unit of the LDO regulator 56 and the DC/DC converter 58. Therefore, the step-down unit of the LDO regulator 56 and the DC/DC converter 58 can output a power supply voltage necessary for the operation of the SSD 14 for a certain period of time.

If data to be written to the flash memory 16 is stored in the DRAM 20, the controller 18 can complete writing of the data to the flash memory 16 within the certain period of time (step S124).

According to the first embodiment, the capacitance of the PLP capacitor 24 is set to a capacitance that is equal to or greater than the capacitance necessary for implementing the PLP function, the capacitance of the PLP capacitor 24 is measured at any time, and a charge voltage for the PLP capacitor 24 is calculated from an energy amount necessary for implementing the PLP function and a value of the measured capacitance. Accordingly, even if the capacitance of the PLP capacitor 24 is decreased to some extent due to aging deterioration, the SSD 14 does not immediately become unusable, and the life of the SSD 14 can be extended. A charge voltage when the capacitance of the PLP capacitor 24 is not decreased is a minimum necessary value. When the capacitance of the PLP capacitor 24 decreases with the use of the SSD 14, the charge voltage is increased. Therefore, since the charge voltage is low at the beginning of use, it is possible to reduce the possibility of a short-circuit failure, thereby extending the life of the SSD 14.

### Second Embodiment

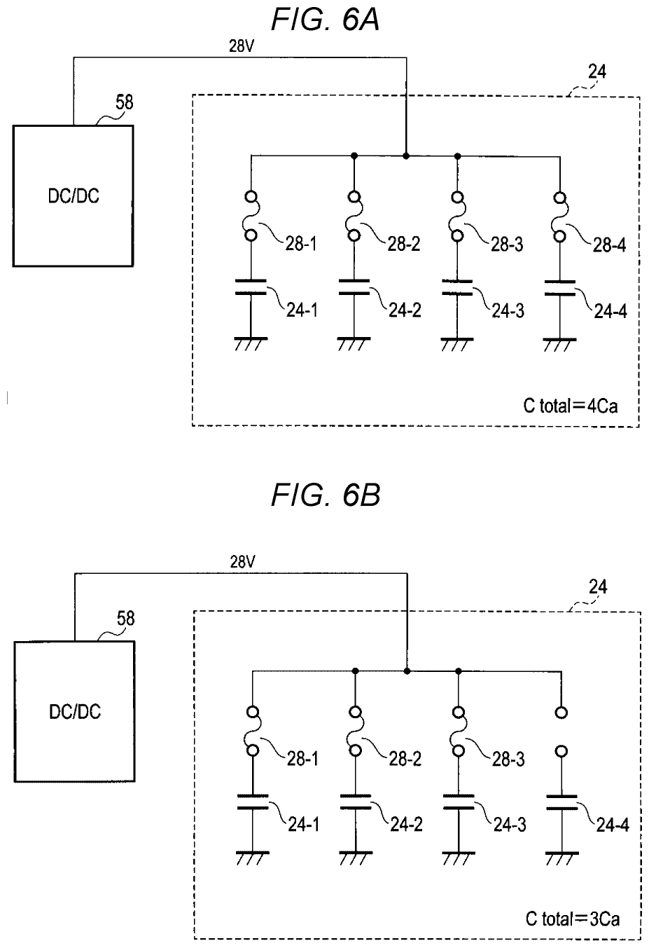

A second embodiment is the same as the first embodiment except for a configuration of the PLP capacitor 24. The PLP capacitor 24 according to the second embodiment, as shown in FIG. 6A, includes a plurality of (for example, four) capacitors 24-1, 24-2, 24-3, 24-4 connected in parallel, and fuses 28-1, 28-2, 28-3, and 28-4 respectively connected in series between the capacitors 24-1, 24-2, 24-3, 24-4 and the DC/DC converter unit 58a. Each of the fuses 28-1, 28-2, 28-3, and 28-4 may be implemented with a metal fuse that is opened when an overcurrent exceeding a certain current flows thereto.

When any one of the capacitors 24-1, 24-2, 24-3, and 24-4, for example, the capacitor 24-4 is short-circuited, as shown in FIG. 6B, an overcurrent flows through the capacitor 24-4 and the fuse 28-4 is blown. The connection point between the blown fuse 28-4 and the DC/DC converter unit 58a is electrically open, and the short-circuited capacitor 24-4 is thus electrically disconnected from the DC/DC converter unit 58a.

A combined capacitance Ctotal of the PLP capacitor 24 in the state of FIG. 6B, where any one of the four depicted fuses is opened/blown, decreases to ¾ of a combined capacitance Ctotal in the state depicted in FIG. 6A. At this time, similarly to the first embodiment, if the output voltage of the DC/DC converter unit 58a, that is, a charge voltage for the PLP capacitor 24, is set according to the combined capacitance Ctotal of the PLP capacitor 24, energy necessary for implementing the PLP function can be charged in the PLP capacitor 24.

The fuses 28-1, 28-2, 28-3, and 28-4 are not limited to metal fuses, and may be implemented with electronic fuses that become non-conductive when an overcurrent is detected.

[Operation Example]

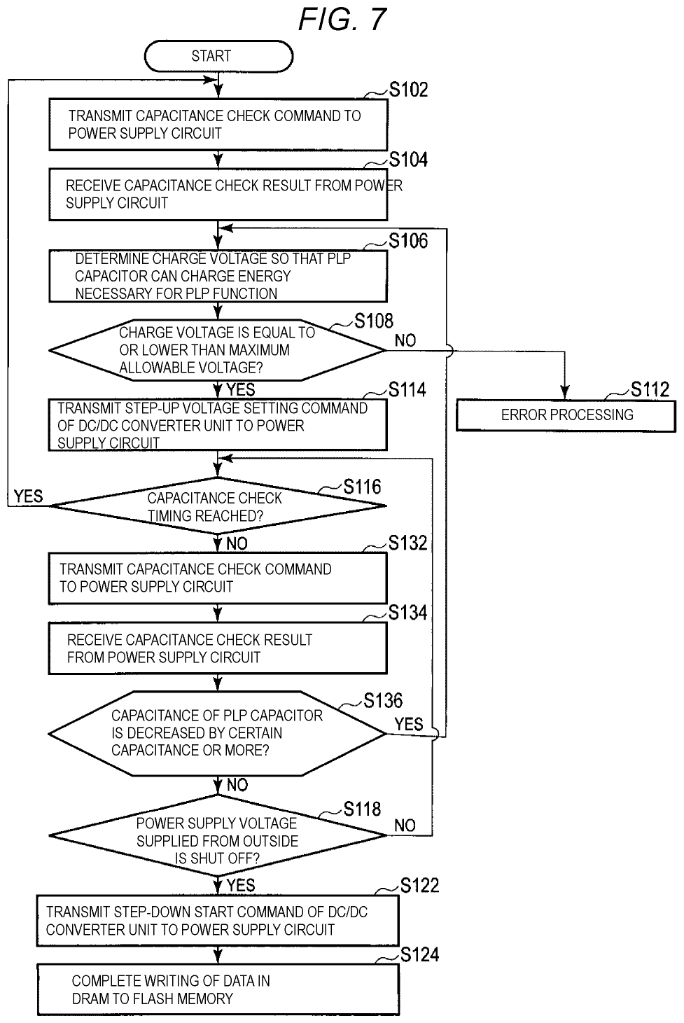

An example of processing related to PLP of the controller 18 will be described with reference to FIG. 7. The same reference numerals denote the same processing as in the first embodiment, and a description thereof will be omitted. The processing in the second embodiment adds several steps between the processing of determining whether the capacitance check timing is reached in step S116 of the first embodiment and the processing of determining whether the external power supply voltage is shut off in step S118.

When the capacitance check timing is not reached (NO in step S116), the controller 18 transmits a capacitance check command to the power supply circuit 22 in step S132. When the control logic 60 of the power supply circuit 22 receives the capacitance check command via the I2C I/F 64, the control logic 60 transmits a measurement result of the capacitance measurement circuit 26 to the controller 18 via the I2C I/F 64 as a capacitance check result.

In step S134, the controller 18 receives the capacitance check result transmitted from the power supply circuit 22.

In step S136, the controller 18 determines whether a combined capacitance of the PLP capacitor 24 is decreased by a certain capacitance or more. The certain capacitance is 1/n when the PLP capacitor 24 is implemented with n capacitors. That is, in step S136, the controller 18 determines whether any one of the capacitors is short-circuited and such a capacitor is disconnected by the opened/blown fuse.

When the short-circuited capacitor is disconnected by the opened/blown fuse and the combined capacitance of the PLP capacitor 24 is decreased by the certain capacitance or more (YES in step S136), the controller 18 calculates a charge voltage sufficient for the PLP capacitor 24 to charge energy necessary for implementing the PLP function in step S106 based on the measurement result of the combined capacitance of the PLP capacitor 24. As shown in FIG. 6B, even if the combined capacitance of the PLP capacitor 24 is decreased to ¾ of the case of FIG. 6A, the same energy as that in the case of FIG. 6A can be charged by increasing the charge voltage to ( 4/3)^{1/2} of the state of FIG. 6A.

When the combined capacitance of the PLP capacitor 24 is not reduced by the certain capacitance or more, it may be determined that no capacitor is short-circuited. Accordingly, the controller 18 determines whether the power supply voltage supplied from the outside is shut off in step S118. When the power supply voltage supplied from the outside is not shut off (NO in step S118) , the controller 18 repeats the determination of step S116.

According to the second embodiment, the PLP capacitor 24 is implemented with a plurality of capacitors 24-1, 24-2, 24-3, 24-4 connected in parallel, and the output current of the DC/DC converter unit 58a is supplied to the capacitors 24-1, 24-2, 24-3, and 24-4 via the fuses 28-1, 28-2, 28-3, and 28-4, respectively. Therefore, when any of the capacitors 24-1, 24-2, 24-3, 24-4 is short-circuited, the corresponding fuse 28-1, 28-2, 28-3, or 28-4 is opened and the short-circuited capacitors 24-1, 24-2, 24-3, or 24-4 can be electrically disconnected from the DC/DC converter unit 58a. Even if the combined capacitance of the PLP capacitor 24 decreases due to the disconnection of the short-circuited capacitor, the PLP capacitor 24 can be charged with an energy amount necessary for implementing the PLP function by increasing the charge voltage. Accordingly, the life of the SSD 14 can be extended.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system, comprising:
a non-volatile memory;
a controller configured to control writing of data to the non-volatile memory;
a power supply circuit that is connected to the non-volatile memory and the controller and is configured to generate a plurality of power supply voltages using an external voltage; and
at least one capacitor configured to store energy that is charged by a charge voltage, which is one of the plurality of power supply voltages generated by the power supply circuit, wherein
a capacitance of the at least one capacitor is detected, and a value of the charge voltage is determined according to the detected capacitance of the at least one capacitor.

2. The memory system according to claim 1, wherein
the value of the charge voltage is set so that an energy amount charged in the at least one capacitor matches a predetermined energy amount.

3. The memory system according to claim 2, wherein
when the detected capacitance of the at least one capacitor is a first capacitance, a first value is used as the value of the charge voltage, and
when the detected capacitance of the at least one capacitor is a second capacitance less than the first capacitance, a second value larger than the first value is used as the value of the charge voltage.

4. The memory system according to claim 1, wherein
the capacitance of the at least one capacitor is detected during power-on of the memory system or at a predetermined time during operation of the memory system.

5. The memory system according to claim 1, further comprising:
a plurality of capacitors connected in parallel.

6. The memory system according to claim 1, wherein
the at least one capacitor is one of a plurality of capacitors connected in parallel,
the plurality of capacitors are connected to the power supply circuit through a plurality of fuses, respectively, and
a combined capacitance of the plurality of capacitors is detected.

7. The memory system according to claim 6, wherein
each of the plurality of fuses includes a metal fuse that is opened when an overcurrent flows or an electronic fuse that becomes non-conductive when an overcurrent is detected.

8. The memory system according to claim 1, wherein
the power supply circuit is configured to detect the capacitance of the at least one capacitor,
the controller is further configured to:
transmit a command that instructs detection of the capacitance of the at least one capacitor to the power supply circuit;
receive a notification including a value of the detected capacitance of the at least one capacitor from the power supply circuit; and
transmit a command for generating the charge voltage having a value corresponding to the detected capacitance of the at least one capacitor to the power supply circuit.

9. The memory system according to claim 8, further comprising:
a volatile memory, wherein
the controller is further configured to:
store data of a write unit in the volatile memory, and
when supply of the external voltage is stopped before writing of the data of the write unit to the non-volatile memory is completed, complete the writing of the data of the write unit to the non-volatile memory using at least one of the plurality of power supply voltages generated by the power supply circuit.

10. The memory system according to claim 9, wherein when the supply of the external voltage is stopped, the energy charged in the at least one capacitor is discharged to the power supply circuit, and the power supply circuit generates the plurality of voltages using the discharged energy.

11. A method of operating a power supply circuit, comprising:
detecting a capacitance of at least one capacitor;
generating, using an external voltage, a charge voltage according to the detected capacitance of the at least one capacitor; and
charging the at least one capacitor with the charge voltage.

12. The method according to claim 11, wherein
the charge voltage is a voltage providing a charged energy amount in the at least one capacitor that matches a predetermined energy amount.

13. The method according to claim 12, wherein
when the detected capacitance of the at least one capacitor is a first capacitance, a first value is used as a value of the charge voltage, and
when the detected capacitance of the at least one capacitor is a second capacitance smaller than the first capacitance, a second value larger than the first value is used as the value of the charge voltage.

14. The method according to claim 11, wherein
the at least one capacitor is one of a plurality of capacitors connected in parallel, and
a combined capacitance of the plurality of capacitors is detected.

15. The method according to claim 11, further comprising:
receiving a command that instructs detection of the capacitance of the at least one capacitor from a controller,
transmitting a notification including a value of the detected capacitance of the at least one capacitor to the controller, and
receiving a command for generating the charge voltage having a value corresponding to the detected capacitance of the at least one capacitor from the controller.

16. The method according to claim 15, further comprising:
generating a plurality of voltages using energy discharged from the at least one capacitor.

17. A memory system, comprising:
a non-volatile memory;
a controller configured to control writing of data to the non-volatile memory;
a power supply circuit that is connected to the non-volatile memory and the controller, and configured to generate a plurality of power supply voltages using at least a voltage supplied from outside; and
a plurality of capacitors configured to store energy that is charged by a charge voltage, which is one of the plurality of power supply voltages generated by the power supply circuit, the plurality of capacitors being connected in parallel and connected to the power supply circuit through a plurality of fuses, respectively, wherein
a combined capacitance of the plurality of capacitors connected in parallel is detected, and a value of the charge voltage is set according to the detected capacitance of the plurality of capacitors connected in parallel.

18. The memory system according to claim 17, wherein the plurality of fuses are respectively connected in series between the plurality of capacitors and the power supply circuit.

19. The memory system according to claim 17, wherein each of the plurality of fuses is a metal fuse that is opened when an overcurrent flows.

20. The memory system according to claim 17, wherein each of the plurality of fuses is an electronic fuse that becomes non-conductive when an overcurrent is detected.
